(19) United States
(12) Patent Application Publication
(10) Pub. No.: US 2009/0321940 A1
(43) Pub. Date: Dec. 31, 2009

(54) Method for Manufacturing Contact Openings, Method for Manufacturing an Integrated Circuit, an Integrated Circuit

(76) Inventors: Gerhard Kunkel, Radebeul (DE); Dirk Manger, Dresden (DE); Stephan Wege, Dresden (DE)

Correspondence Address: SLATER & MATSIL, L.L.P., 17950 PRESTON ROAD, SUITE 1000, DALLAS, TX, 75252, US

(21) Appl. No.: 12/165,093

(22) Filed: Jun. 30, 2008

(51) Int. Cl. H01L 21/768; H01L 23/522

(52) U.S. Cl. 257/758; 438/637; 257/E21.585; 257/E23.145

(57) ABSTRACT

An integrated circuit is described including a first and a second plurality of conductor lines, each of the lines being separated from an adjacent line by a spacer dielectric and capped with a first and second dielectric cap material, respectively. A contact element is embedded in a covering dielectric layer with electrical contact to one of the first plurality of conductor lines in a contact portion, while being separated from a line adjacent to the contacted line only by the second cap material.

### BACKGROUND

In the manufacturing of semiconductor devices, in particular integrated circuits contact openings to conductor lines have to be manufactured to establish electrical contacts between different layers of a layered stack. Semiconductor devices can be, e.g., microprocessors, memory chips, DRAM chips, flash memory chips, optoelectronic devices or bio-chips. The person skilled in the art will recognize that establishing contact openings is also applicable to other types of semiconductor devices.

Therefore, methods for manufacturing contact openings to underlying conductor lines are needed. In many cases, the width or center position of the line is different from the width or center position of the contact opening, and the opened area overlaps with adjacent conductor lines.

In the following drawings implementations showing different aspects of the invention are depicted. The person skilled in the art will recognize that these implementations are just examples.

### BRIEF DESCRIPTION OF THE DRAWINGS

FIG. 1 schematically shows a cross section of an initial layer stack of a semiconductor device according to an implementation;

FIG. 2 schematically shows an implementation of the stack depicted in FIG. 1 after a first process;

FIG. 3 schematically shows an implementation of the stack depicted in FIG. 2 after a second process involving the conformal deposition of a spacer layer;

FIG. 4 schematically shows an implementation of the stack depicted in FIG. 3 after the partial removal of the spacer layer;

FIG. 5 schematically shows an implementation of the stack depicted in FIG. 4 after the filling of gaps with conducting material;

FIG. 6 schematically shows an implementation of the stack depicted in FIG. 5 after the application of a second and third mask layer;

FIG. 7 schematically shows an implementation of the stack depicted in FIG. 6 with a contact opening;

FIG. 7A schematically shows an implementation of the stack depicted in FIG. 7 with a contact opening slightly misaligned;

FIG. 8 schematically shows an implementation of a stack with two contact opening;

FIG. 9 schematically shows an implementation of a stack with a contact opening to bridge between two contacts;

FIG. 10 schematically depicts a further implementation of a semiconductor device being a starting point of an implementation of the method;

FIG. 11 schematically depicts an implementation of the stack shown in FIG. 10 after the application of a second and third mask layer;

FIG. 12 schematically shows an implementation of the stack depicted in FIG. 11 with a contact opening;

FIG. 12A schematically shows an implementation of the stack depicted in FIG. 11 with a contact opening slightly misaligned;

FIG. 13 schematically shows an implementation of a stack with a contact opening over a first conductor line;

FIG. 14 schematically shows an implementation of a stack with a contact opening over a second conductor line;

FIG. 15 schematically shows an implementation of a stack with a filled contact opening over a second conductor line;

FIG. 16 shows a flowchart for a first implementation of the method; and

FIG. 17 shows a flowchart for a second further implementation of the method.

### DETAILED DESCRIPTION OF ILLUSTRATIVE EMBODIMENTS

The following schematic figures show different implementations of processes which can be used in the manufacturing of semiconductor devices. Furthermore, the figures represent implementations of intermediate products in the manufacturing of semiconductor devices.

The implementations refer to the manufacturing of an array of conductor lines as an example. In particular, the implementations refer to dense conductor lines and space arrays which can be used in memory chips such as DRAM chips. But the methods and intermediate devices are also applicable to conductor lines which are not positioned in a regular arrangement such as an array.

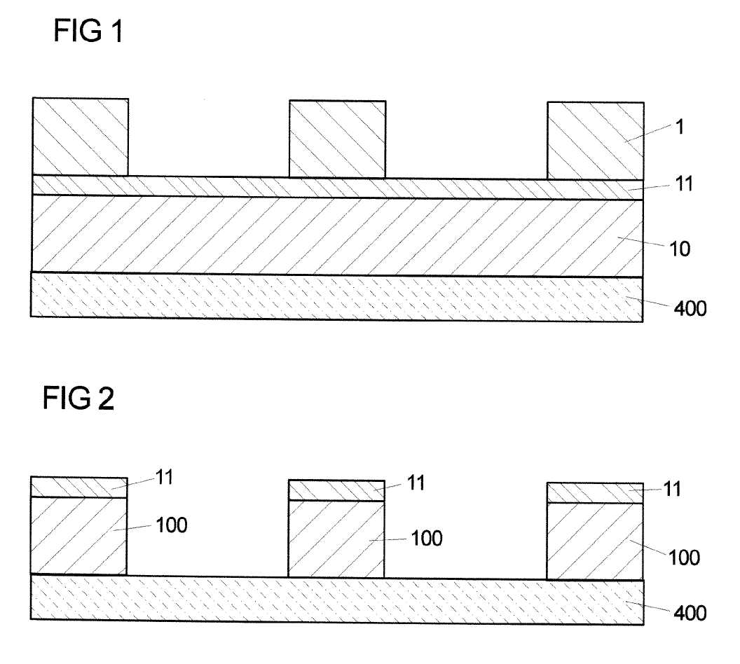

In FIG. 1 a cross section through a layered stack with a base substrate 400 showing a part of a first implementation, in which a metal layer 10 is covered at least partially with a first mask layer 11. In FIG. 1 a complete covering of the first mask layer 11 is depicted but this is not mandatory, i.e., certain areas of the metal layer 10 can be free of the first mask layer.

Furthermore, it should be noted that the layer depicted in FIG. 1 and the following figures can be just parts of a more complex structure, i.e., more layers, not shown in the figures for the sake of simplicity, can be situated underneath the metal layer 10.

As will be shown below, conductor lines 100, 200 will be manufactured from the metal layer 10. The metal layer 10 can comprise metals such as tungsten, titanium, copper, aluminum, polysilicon, AlCu, WSiₓ, metal silicides and Metal-Silicon alloys.

The first mask layer 11 in this implementation is a hard mask layer comprising, e.g., SiN, SiO₂, Al₂O₃, SiOCN, black diamond, SiCOH and SiC:H.

On top of the first mask layer 11 a resist 1 has been positioned which in FIG. 1 has been already structured by methods generally known in the art.

The layered stack according to the implementation depicted in FIG. 1 is subjected to an etch process, such, e.g., a reactive ion etching (RIE).

FIG. 2 shows the result of this process. The metal layer 10 is separated into parallel lines of conducting material, the top of each line is covered by the remaining first mask layer 11 material. In the following these lines of conduction material will be termed first conductor lines 100. There are gaps between the first conductor lines 100. In the implementation shown here in an exemplary way, the conductor lines 100 are parallel.

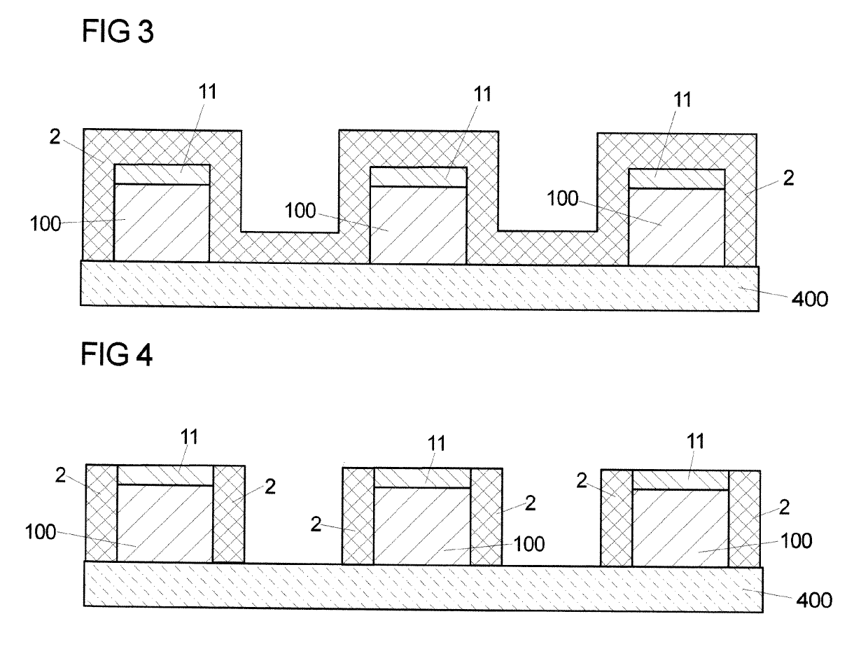

FIG. 3 shows the result of further processing of the layered stack in FIG. 2. The first conductor lines 100 together with the remaining first mask layer 11 are covered with a spacer 2 material which is conformally deposited. The dielectric spacer material 2 can comprise SiO₂ or SiN. These spacer materials 2 can be deposited in very thin layers.

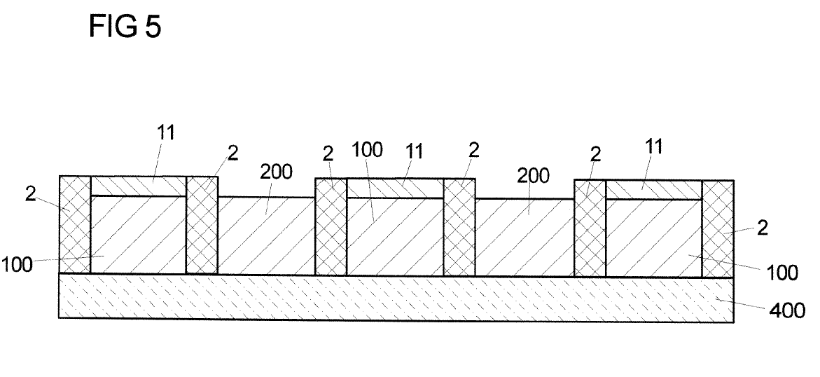

FIG. 4 shows the result of further processing of the layered stack in FIG. 3. The spacer 2 material, which is positioned horizontally, has been anisotropically etched by a chlorine or fluorine based plasma etch. In principle other anisotropic etching processes are possible. The result is that the first mask layer 11 and the gaps between the first conductor lines 100 are free of spacer material 2. The sidewalls of the first conductor lines 100 are covered by the spacer material 2. Since in the depicted implementation the spacer material is deposited on all sidewalls of the first conductor lines 100, the gap between the first conductor lines 100 has been narrowed somewhat.

FIG. 5 shows the result of further processing of the layered stack in FIG. 4. Conducting material is positioned in the gaps between the first conducting lines 100. This conducting material in the gaps now forms a plurality of parallel second conductor lines 200. In principle this processing could be termed as a damascene process since conducting material is positioned between dielectric material of the spacers 2.

In FIG. 5 the second conductor lines 200 are depicted somewhat recessed compared to the other parts of the stack. In an alternative processing, the gap could be overfilled with conducting material and then polished with CMP resulting in a leveled surface of the stack.

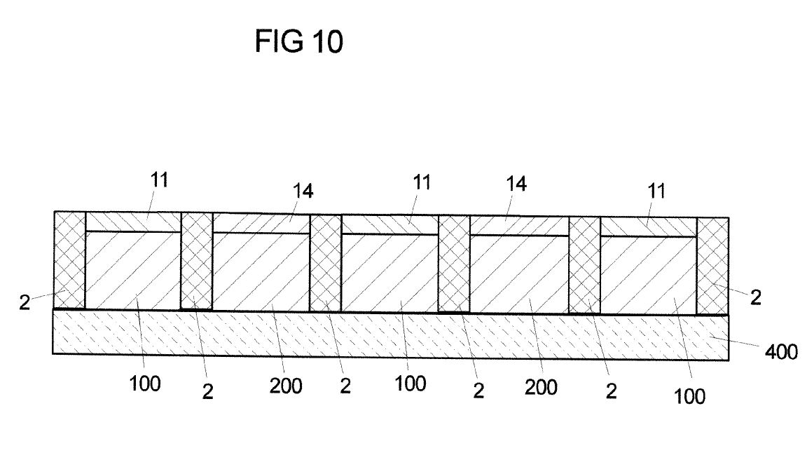

It should be noted that the implementation shown in FIG. 1 to 5 can be achieved in various ways. In FIG. 2 a plurality of conductor lines 100 is shown, each one capped with a dielectric cap 11, which, in the implementation shown in FIG. 2, has been derived from the first mask layer 11. In alternative implementation, this could be positioned in a different way. Furthermore, in FIG. 5 the plurality of conductor lines 100 is shown with caps of dielectric material. The dielectric materials of adjacent conductor lines 100, 200 can be different (see FIG. 10). In an implementation, conductor lines 200 are not capped by a dielectric material.

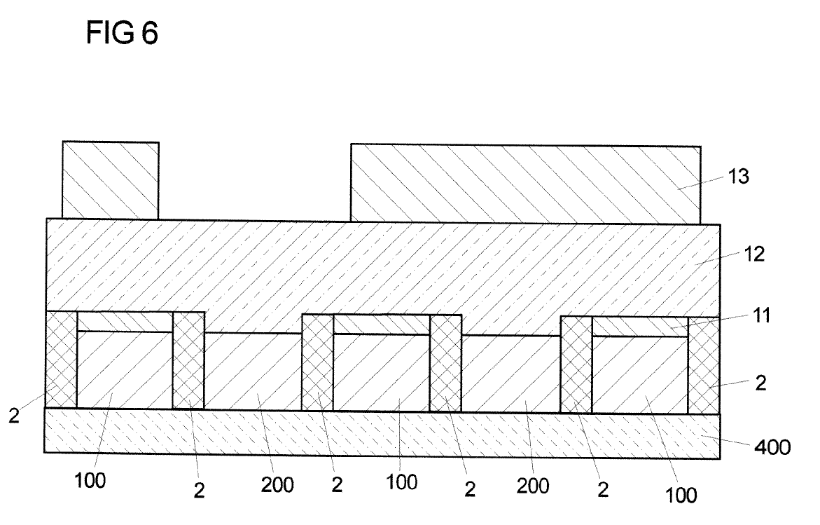

FIG. 6 shows the result of further processing of the layered stack in FIG. 5. The stack has been covered with a second mask layer 12. The second mask layer 12 comprises a dielectric layer, e.g., an oxide.

A third mask layer 13 is deposited on top of the second mask layer 12. In FIG. 6 the third mask layer 13, comprising a resist, is already structured by lithography known in the art.

As will become clear from the following description of the process, the materials of the first mask layer 11, the second mask layer 12 and the third mask layer 13 can be etched selectively. As an example, the first mask layer 11 comprises a nitride, the second mask layer 12 comprises an oxide and the third mask layer 13 comprises a resist.

In one possible implementation, the first mask layer 11 can comprise silicon nitride SiN, the second mask layer 12 can comprise silicon oxide (SiO₂). The third mask layer 13 can comprise resist or carbon as a mask or hard mask material. The spacer material 2 can comprise SiN. In an alternative implementation, the first mask layer 11 can comprises Al₂O₃.

The etching could be performed in a CCP reactor using an etch medium comprising Ar (400 sccm), C₄H₆ (50 sccm), O₂ (15 sccm). Alternatively the etching could be performed by using an etching medium comprising Ar (200 sccm), C₄H₈ (30 sccm), CO (250 sccm), O₂ (15 sccm). Pressures can be 10 to 20 mTorr.

In another possible implementation, the second mask layer 12 can comprise SiN. In this case the first mask layer 11 and the spacer material 2 can comprise SiO₂ or Al₂O₃ (for the first mask layer 11). The third mask layer 13 can comprise a resist or carbon. One possible etching process can use Ar (400 sccm), CH₃F (50 sccm) and O₂ (50 sccm).

A person skilled in the art will recognize that these etching conditions can be varied and are given here just as an example.

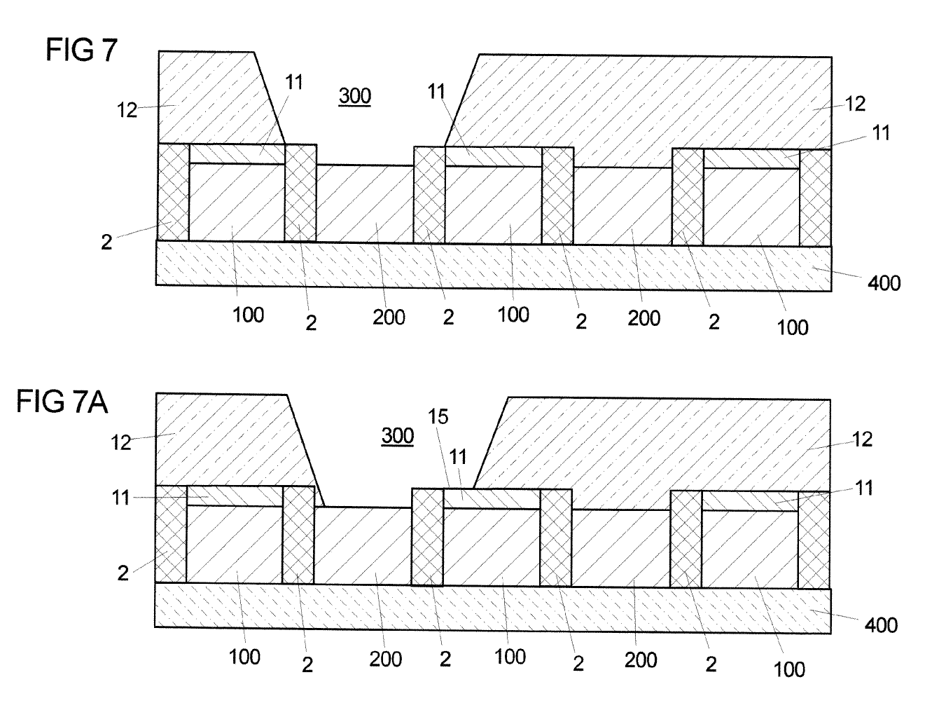

FIG. 7 shows the result of further processing of the layered stack in FIG. 6. The third mask layer 13 has been used to structure the second mask layer 12 to open a contact opening 300 (can also termed as contact hole). The oxide etch of the second mask layer 12 is selective to the spacer material which would be a nitride in this case.

The contact opening 300 opens towards one of the second conductor lines 200.

The implementation of FIG. 7 assumes essentially good alignment of the structuring of the second mask layer 12 and the second conductor line 200. However, in case of some degree of misalignment, or if the width of the opening exceeds the width of the opened second conductor line 200, the contact opening could also open toward the capping of an adjacent first conductor line 100 in a separation portion (see, e.g., FIG. 7A). For example, if the first and second conductor lines are manufactured by a method of pitch fragmentation (or double patterning), the width of the conductor lines may be sub-lithographic, while the width of the opening may be lithographic. In such a case, the capping of an adjacent conductor line may be opened. However, if the capping of an adjacent conductor line is not removed during the formation of the contact opening, it is possible to contact a conductor line having a width with a contact opening having a larger width without shortening to an adjacent conductor line.

In an alternative implementation, which is also depicted by FIG. 7, a contact opening 300 is formed by an anisotropic etch in the dielectric layer, which can be the second mask layer 12, thereby exposing a surface of the at least one conductor line 100, 200. The anisotropic etch of the dielectric layer is selective to the spacer 2 dielectric and the cap material from the adjacent conductor lines.

Such a structure can be part of a semiconductor device, such as an integrated circuit.

FIG. 7A shows that even with a misaligned structuring of the second mask layer 12, the contact opening 300 would be positioned effectively, i.e., making contact with the conductor line 200. Part of the contact opening 300 exposes the dielectric material of the first hard mask 11 in a separation portion 15, so that no contact is made to the first conductor line 100 which is effectively isolated against the contact opening 300 by the first hard mask 11.

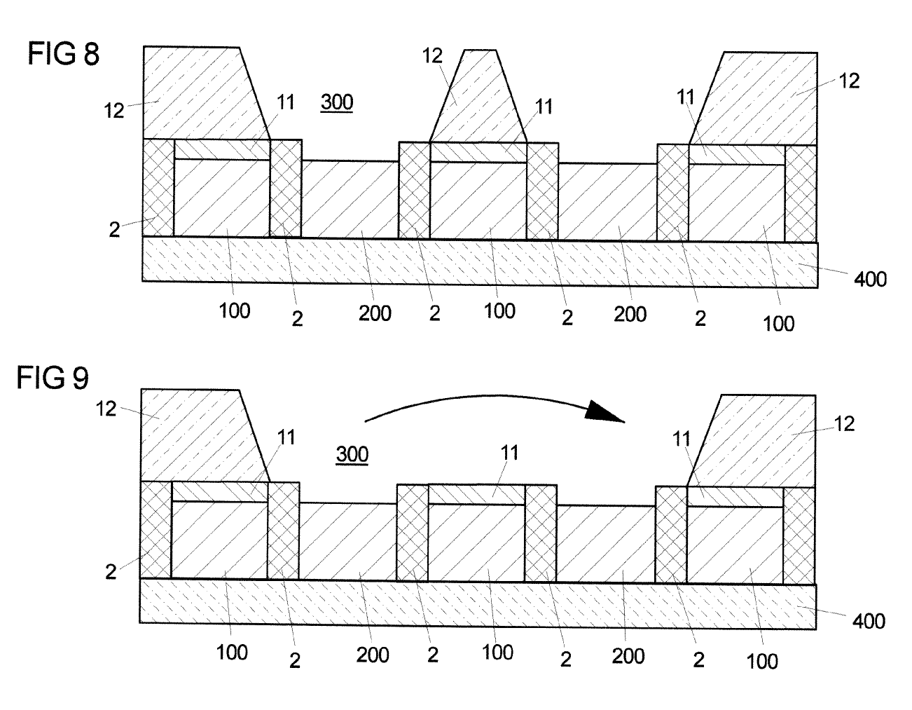

In FIG. 8 a different implementation of the processing is depicted. In this implementation, a contact opening 300 is placed over every second of the second conductor lines 200. The contact openings 300 are placed over the second conductor lines 200 not being covered by the first mask layer 11. The person skilled in the art will recognize that by using patterns of conductor lines, as, e.g., shown in FIG. 5, every second or every multiple thereof might be contacted through a contact opening 300 as shown in FIG. 8.

Furthermore, the person skilled in the art will recognize that in an alternative process the first conductor lines 100 could be contacted through contact openings 300, while the second conductor lines 200 would be covered by a mask layer.

FIG. 9 shows another implementation is shown. In this case the contact opening 300 in the second mask layer 12 extends over a wider range, i.e., at least two second conductor lines 200 can be contacted through a contact opening 300. When the contact opening 300 would be filled with a conducting material, the two second conductor lines 200 would be conductively bridged as indicated by the arrow.

In FIG. 10 a further implementation is shown, which uses a variant of the situation depicted in FIG. 5. In FIG. 5 a first mask layer 11 is covering the first conductor lines 100. The second conductor lines 200 are not covered by a mask layer.

In the implementation shown in FIG. 10, the first conductor line 100 is covered by a first mask layer 11 as well, but the second conductor lines 200 are covered with a fourth mask layer 14. FIG. 10 shows the layered stack after a planarization using e.g. CMP.

Like in the implementation depicted in FIG. 5, the conductor lines 100, 200 are separated by spacers 2. The processing described in connection with FIG. 1 to 4 are also applicable to the implementation shown in FIG. 10. The plurality of conductor lines 100, 200 and the spacers between them can be formed as described in FIG. 1 to 4, e.g., by etching first conductor lines 100 (FIG. 2), forming a spacer 2 (FIGS. 3 and 4). The gaps between the spacer 2 material is filled with conductive material (FIG. 5), and capped with a fourth mask layer 14.

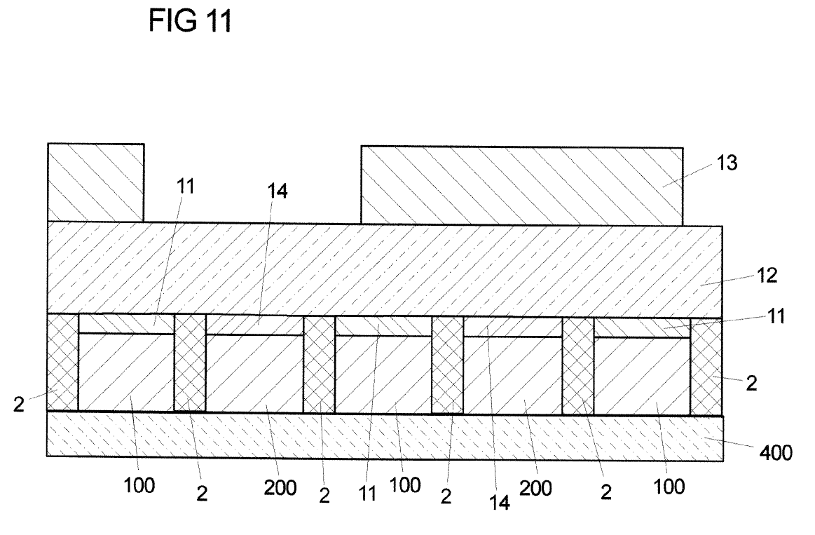

In FIG. 11, which is analogous to FIG. 6, a second mask layer 12 and a third mask layer 13 are positioned over the existing stack. The third mask layer 13 comprising resist is already structured.

The second mask layer 12 is then structured using conventional lithography techniques, as described in connection with FIG. 7, 7A. The difference is that the fourth mask layer 14 over the second conductor line 200 has to be removed by anisotropic etching.

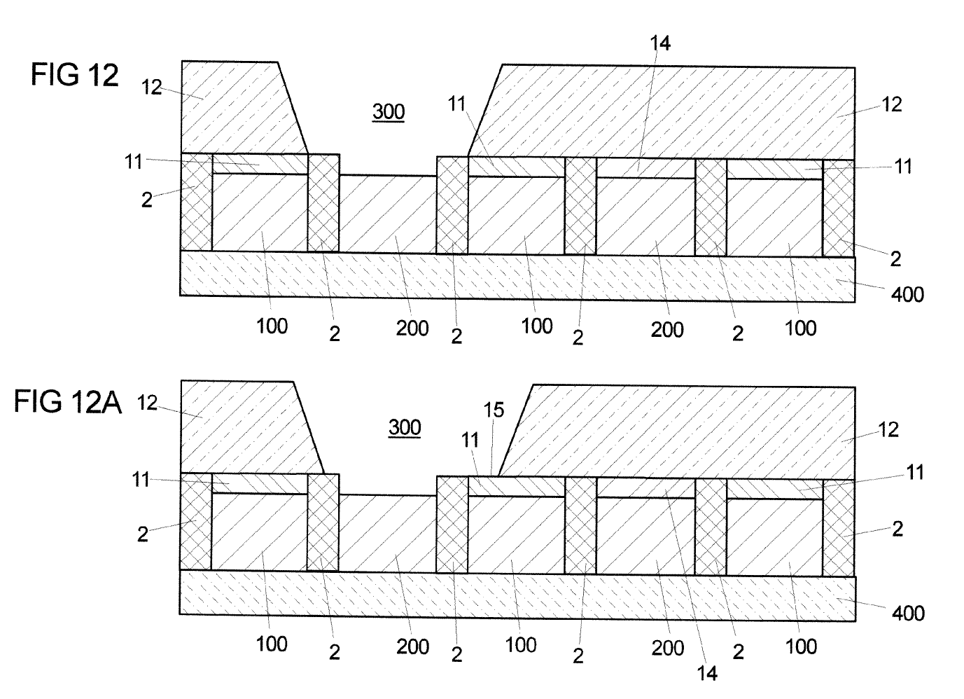

Like in FIG. 7, FIG. 12 shows a good alignment. FIG. 12A shows a degree of misalignment exposing a separation portion 15 of the mask layer covering the adjacent conductor line. In both cases the contact opening 300 can make contact even if the structuring of the second mask layer 12 is less than perfect.

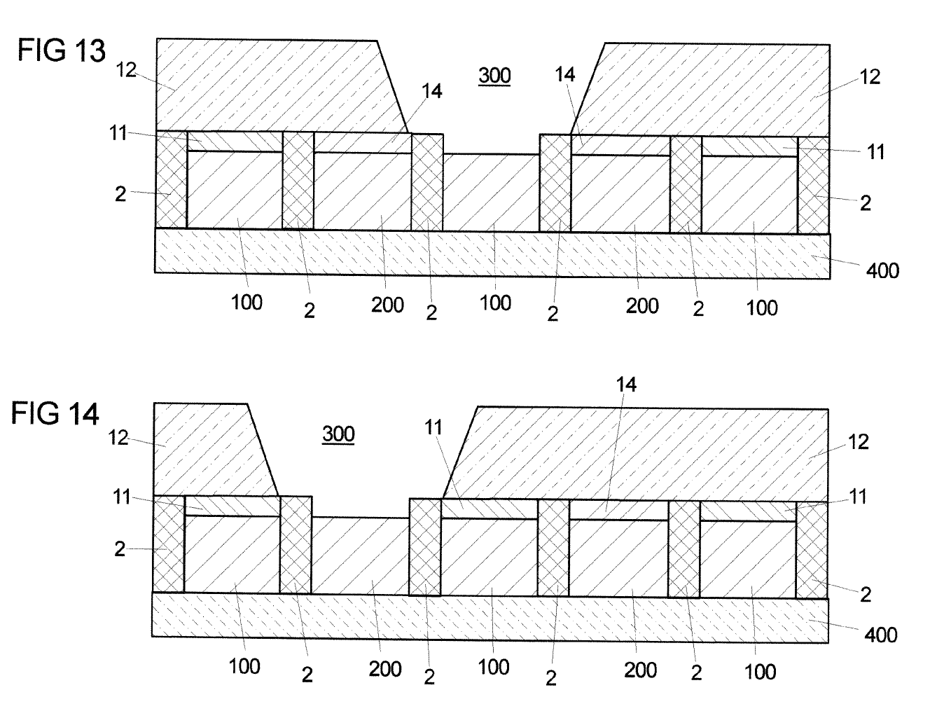

Since the conductor lines 100, 200 are covered by different mask layers 11, 14, each individual conductor line 100, 200 can be contacted with a contact opening, 300 as shown in FIG. 13 for the case of the first conductor line 100 and in FIG. 14 for the second conductor line 200.

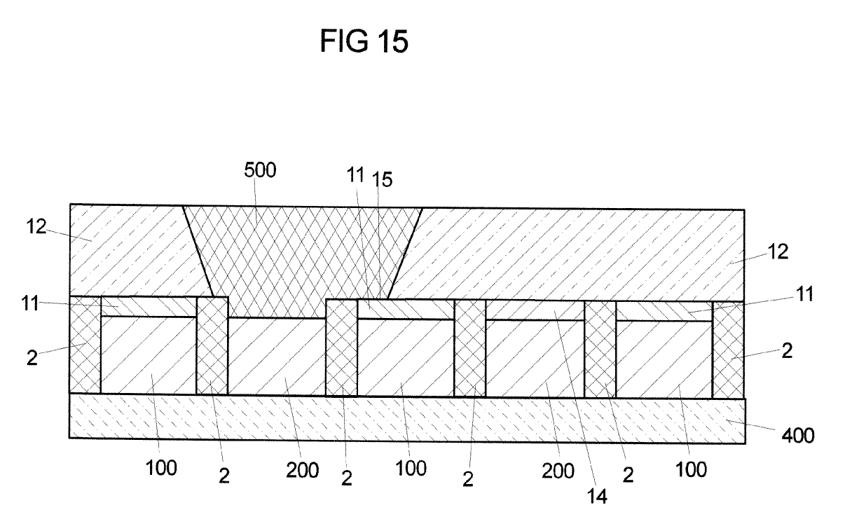

In FIG. 15 a contact element 500 filling a contact opening 300 is schematically shown. The person skilled in the art will recognize that the shape of the contact element 500 can be different from the one depicted in FIG. 15.

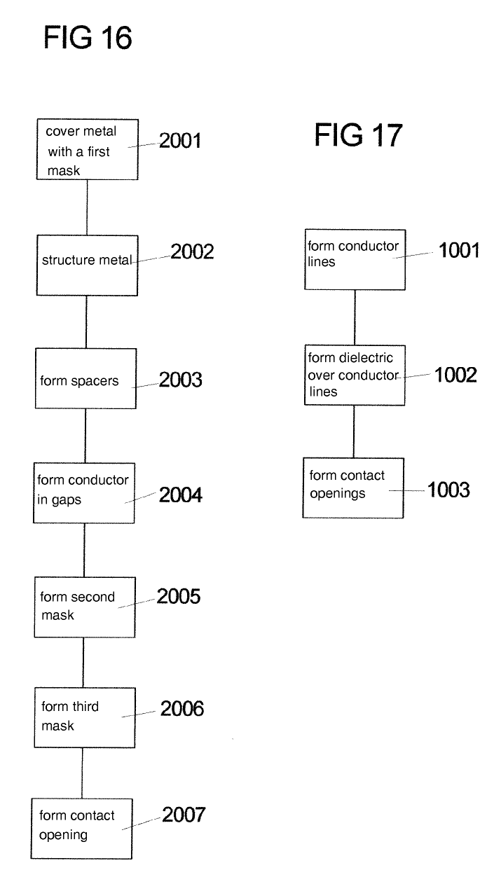

In FIG. 16 a flowchart depicting a first implementation of a method for manufacturing contact openings to at least one conductor line in a semiconductor device is shown. The method comprises the following.

Covering a metal layer at least partially with a first mask layer (2001). Then said metal layer is at least partially structured using a resist layer to form a plurality of first conductor lines with a gap between the first conductor lines (2002). On the sidewalls of the first conductor lines spacers are formed (2003). Then conducting material is positioned in the gaps forming a plurality of parallel second conductor lines (2004). A second mask layer is deposited at least partially on the formed layered stack (2005). A third mask layer is deposited at least partially on the formed layered stack wherein the materials of the first mask layer, the second mask layer and the third mask layer can be etched selectively (2006) and the second mask layer is structured using the third mask layer, so that at least one contact opening is established for at least one of the conductor lines (2007).

In FIG. 17 a flowchart depicting a second implementation of a method for manufacturing contact openings to at least one conductor line in a semiconductor device is shown. The method comprises the following.

Providing a plurality of conductor lines, each line capped with a dielectric cap, and separated from an adjacent conductor line by a spacer dielectric, wherein each conductor line is capped by a dielectric cap material different from the dielectric cap material of an adjacent conductor (1001). Depositing a dielectric layer onto the conductor lines (1002) and forming contact openings by anisotropic etch in the dielectric layer, thereby exposing an upper surface of at least one of the conductor lines (1003).

The person skilled in the art will further recognize that after the manufacturing of the contact opening 300 an intermediate product has been manufactured which can be like one of the implementations shown in FIG. 8, 9, 13 or 14. Usually, these structures are then further processed, by, e.g., filling the contact openings 300 with conducting material.

Furthermore, the person skilled in the art will recognize that other methods or procedures can yield equivalent structures and that the structures shown here can be manufactured by equivalent modifications of the methods.

What is claimed is:

1. A method for manufacturing contact openings to at least one conductor line in a semiconductor device, the method comprising:
covering a metal layer at least partially with a first mask layer;
structuring the metal layer at least partially using a resist layer thereby forming a plurality of first conductor lines with a gap between the first conductor lines;
forming spacers on sidewalls of the first conductor lines;
forming conducting material in the gaps thereby forming a plurality of parallel second conductor lines;
forming a second mask layer at least partially over the first and/or second conductor lines;
forming a third mask layer at least partially over the first and/or second conductor lines, wherein materials of the first mask layer, the second mask layer and the third mask layer can be etched selectively, with respect to each other; and
structuring the second mask layer using the third mask layer, thereby forming at least one contact opening for at least one of the first and/or second conductor lines.

2. The method according to claim 1, wherein the at least one contact opening is formed for every second conductor line.

3. The method according to claim 1, wherein the at least one contact opening is formed for a multiple of every second conductor line.

4. The method according to claim 1, wherein at least two conductor lines are bridged by conducting material after forming at least one contact opening.

5. The method according to claim 1, further comprising after forming the conducting material forming a fourth mask layer over the second conductor lines, the material of the fourth mask layer being selectively etchable with respect to the material of the first mask layer.

6. The method according to claim 1, wherein the spacers are formed by a conformal deposition and a subsequent anisotropic etching.

7. The method according to claim 1, wherein the conducting material forming the second conductor lines is recessed.

8. The method according to claim 1, wherein at least one of the first and/or second mask layer comprises a material selected from the group consisting of SiN, SiO₂, Al₂O₃, SiOCN, black diamond, SiCOH and SiC:H.

9. The method according to claim 1, wherein the third mask layer comprises a resist.

10. The method according to claim 1, wherein the spacer comprises conformal dielectric material.

11. The method according to claim 1, wherein the spacer comprises SiO₂ or SiN.

12. The method according to claim 1, wherein the first conductor lines comprise a material selected from the group consisting of tungsten, titanium, copper, aluminum, polysilicon, AlCu, metal silicide and a metal-silicon alloy and wherein the second conductor lines comprise a material selected from the group consisting of tungsten, titanium, copper, aluminum, polysilicon, AlCu, metal silicide and a metal-silicon alloy.

13. The method according to claim 1, wherein the second conductor lines are at least partially part of a sublithographic structure.

14. The method according to claim 1, wherein the second conductor lines are at least partially manufactured by the use of pitch fragmentation techniques.

15. The method according to claim 1, wherein the first mask layer is structured using a reactive ion etch process prior to structuring the metal layer.

16. The method according to claim 1, wherein the semiconductor device comprises a microprocessor, a memory chip, a DRAM chip, a flash memory chip, an optoelectronic chip or a bio-chip.

17. A method of manufacturing an integrated circuit, the method comprising:
providing a plurality of conductor lines, each line capped with a dielectric cap, and separated from an adjacent conductor line by a spacer dielectric, wherein each conductor line is capped by a dielectric cap material different from the dielectric cap material of an adjacent conductor;
depositing a dielectric layer over the conductor lines; and
forming contact openings by anisotropic etch in the dielectric layer, thereby exposing an upper surface of at least one of the conductor lines,
wherein the anisotropic etch etches the dielectric cap selective to the spacer dielectric and the dielectric cap material from the adjacent conductor line.

18. The method of claim 17, further comprising filling the contact openings with a conductive material.

19. The method of claim 17, wherein the dielectric layer comprises silicon oxide.

20. The method of claim 17, wherein the conductor lines comprise one material selected from the group of tungsten, titanium, copper, aluminum, polysilicon or metal silicides.

21. The method of claim 17, wherein the dielectric cap materials are selected from the group consisting of SiN, SiO₂, Al₂O₃, SiOCN, black diamond, SiCOH and SiC:H.

22. The method of claim 17, wherein providing the plurality of conductor lines comprises:
forming a first plurality of conductor lines from a first conductive material, with gaps arranged between ones of the first plurality of conductor lines;
forming the spacer dielectric at least on sidewalls of the first plurality of conductor lines, thereby forming a remaining gap between ones of the first plurality of conductor lines; and
filling the remaining gap with a second conductive material, thereby forming a second plurality of conductor lines,
wherein the plurality of conductor lines comprise the first and second plurality of conductor lines.

23. The method of claim 22, wherein the first conductive material and the second conductive material are the same material.

24. The method of claim 17, wherein forming the contact opening comprises exposing an upper surface of the dielectric cap of an adjacent line to the at least one of the conductor lines is exposed, but the underlying adjacent line is not exposed.

25. An integrated circuit comprising:
a first and a second plurality of conductor lines, each of the lines being separated from an adjacent line by a spacer dielectric and covered with a dielectric layer; and
a contact element embedded in the dielectric layer and having electrical contact to one of the first plurality of conductor lines in a contact portion,
wherein each line of the first plurality of conductor lines is capped with a first dielectric cap material, and each line of the second plurality of conductor lines is capped with a second dielectric cap material different from the first dielectric cap material, wherein the dielectric layer comprises a material different from the spacer dielectric, the first dielectric cap material and the dielectric second cap material, and wherein the contact element is separated from a line adjacent to the contacted line in a separation portion by the second dielectric cap material.

26. The integrated circuit of claim 25, wherein the spacer dielectric comprises a material different from the first and second dielectric cap materials.

27. The integrated circuit of claim 25, wherein at least one of the first and/or second dielectric cap material comprises a material selected from the group consisting of SiN, SiO₂, Al₂O₃, SiOCN, black diamond, SiCOH and SiC:H.

28. The integrated circuit of claim 25, wherein at least one of the first and/or second plurality of conductor lines comprise a material selected from the group consisting of tungsten, titanium, copper, aluminum, polysilicon and metal silicides.

29. The integrated circuit of claim 25, wherein the contact element comprises a second contact portion to a further line of the first plurality of conductor lines.

30. The integrated circuit of claim 25, wherein the contact element laterally extends over a first subset of the first plurality of conductor lines and over a second subset of the second plurality of conductor lines, and wherein the contact element electrically contacts each of the first subset of lines, and is separated from each of the second subset of lines by the second dielectric cap material.
